(19) United States
(12) Patent Application Publication
(10) Pub. No.: US 2015/0318766 A1
(43) Pub. Date: Nov. 5, 2015

(54) RF Filter And Motor Having The Same

(71) Applicant: Johnson Electric S.A., Murten (CH)

(72) Inventors: Qing Bin LUO, Shenzhen (CN); Chi Wai LAI, Hong Kong (CN); Xiao Lin REN, Shenzhen (CN); Gui Hong TIAN, Shenzhen (CN); Xin Peng WEI, Shenzhen (CN)

(21) Appl. No.: 14/701,178

(22) Filed: Apr. 30, 2015

(30) Foreign Application Priority Data
Apr. 30, 2014 (CN) 201410182388.1
Aug. 7, 2014 (CN) 201410387151.7

(51) Int. Cl. H02K 11/02; H03H 7/01

(52) U.S. Cl. CPC H02K 11/022; H03H 7/01

(57) ABSTRACT

A motor includes motor terminals for connecting with an external power supply and an internal circuit connected to the motor terminals. The motor further includes a RF filter. The RF filter includes a conductive wire coiled in either a helical manner or a spiral manner. Terminals of the conductive wire at opposite axial ends of the coil are connected to a corresponding one of the motor terminals and the internal circuit, respectively. The intensity of the electromagnetic waves radiated from most parts of the conductive wire of the RF filter is attenuated by reflected electromagnetic waves from other parts of the conductive wire. Therefore, the intensity of the electromagnetic wave radiated from the motor is greatly reduced. A RF filter for the motor is also provided.

### CROSS REFERENCE TO RELATED APPLICATIONS

This non-provisional patent application claims priority under 35 U.S.C. §119(a) from Patent Application No. 201410182388.1 filed in The People's Republic of China on Apr. 30, 2014 and Patent Application No. 201410387151.7 filed in The People's Republic of China on Aug. 7, 2014, the entire contents of which are hereby incorporated by reference.

### FIELD OF THE INVENTION

This invention relates to radio frequency (RF) filtering technology and in particular, to a RF filter and a motor incorporating the RF filter.

### BACKGROUND OF THE INVENTION

A stator of a miniature permanent magnet direct current brush motor typically includes a cup-shaped housing, a plurality of permanent magnets fixed to an inner surface of the housing, and an end cap enclosing an opening of the outer housing. The end cap usually includes brushes and motor terminals electrically connected to the brushes. The motor terminals extend through the end cap for connection to an external power supply to supply power to the brushes. The motor terminals and the brushes are usually connected by straight conductive wires or strips. However, during operation of the motor, RF (radio frequency) signals produced by an internal circuit of the motor may be coupled to and hence radiated outwards by the conductive wire or strips, which causes the motor to produce an unduly large electromagnetic radiation signal.

As there is a requirement or demand to reduce RF emissions, there is a desire for a RF filter to reduce the electromagnetic radiation emission from the a motor as the emission of RF signals.

### SUMMARY OF THE INVENTION

Accordingly, in one aspect thereof, the present invention provides a RF filter comprising a conductive wire, the conductive wire coiled on a hypothetical cylindrical surface in a helical manner to form a hollow cylindrical coil, or in a plane in a spiral manner to form a spiral coil, terminals of the conductive wire at opposite ends of the coil forming an input end and an output end of the RF filter.

Preferably, the conductive wire is wrapped with an outer insulating material.

According to a second aspect thereof, the present invention provides a motor comprising: motor terminals for connecting with an external power supply; an internal circuit electrically connected to the motor terminals; and a RF filter connecting the internal circuit to one of the motor terminals, wherein the RF filter comprises a conductive wire formed in a coil having first and second terminals, the first terminal being connected to one of the motor terminals and the second terminal being connected to the internal circuit, the coil being wound in a manner to attenuate electromagnetic radiation from the motor.

Optionally, the conductive wire is coiled on a hypothetical cylindrical surface in a helical manner to form a hollow cylindrical coil.

Preferably, the motor comprises two such RF filters, with the first terminal of each coil being connected to a respective one of the motor terminals.

Preferably, the conductive wires of the two RF filters extend in parallel on the same hypothetical cylindrical surface in the same helical direction, and at least one of the conductive wires is wrapped with an outer insulating material.

Alternatively, the RF filter comprises a conductive wire coiled in a plane in a spiral manner to form the coil.

Preferably, the motor comprises two such RF filters, with the first terminal of each coil being connected to a respective one of the motor terminals.

Preferably, the conductive wires of the two RF filters are coiled together in a single plane.

Preferably, the motor comprises two such RF filters, and the coils of the two RF filters are symmetrically disposed in two parallel planes.

Preferably, the motor comprises two such RF filters, and the conductive wires are conductive traces formed on a circuit board.

Alternatively, the motor further comprises a circuit board, each RF filter is printed on the circuit board and is electrically connected to the internal circuit through a printed circuit on the circuit board.

Optionally, the motor further comprises a circuit board with a printed circuit, the RF filter is printed on the circuit board and is electrically connected with the connecting terminals and internal circuit through the printed circuit on the circuit board.

Preferably, the circuit board includes a first surface and a second surface, the RF filter includes a first RF filter portion printed on the first surface and a second RF filter portion printed on the second surface, the first RF filter portion and the second RF filter portion are aligned with each other and are connected in series through a hole in the circuit board.

Preferably, the conductive wire of at least one of the RF filters has an insulating cover.

Preferably, rings of the coil are in the shape of one of a circle, an oval, a triangle, a square, and a polygon.

Preferably, the conductive wire extends in a plane to expand outwardly in a continuous ring-by-ring manner.

In the RF filter of the present invention, the intensity of the electromagnetic waves radiated outwardly from most parts of the conductive wire of the RF filter is more or less attenuated by reflected electromagnetic waves from other parts of the conductive wire. Therefore, the intensity of the electromagnetic wave emitted by the entire RF filter is greatly reduced.

### BRIEF DESCRIPTION OF THE DRAWINGS

A preferred embodiment of the invention will now be described, by way of example only, with reference to figures of the accompanying drawings. In the figures, identical structures, elements or parts that appear in more than one figure are generally labeled with a same reference numeral in all the figures in which they appear. Dimensions of components and features shown in the figures are generally chosen for convenience and clarity of presentation and are not necessarily shown to scale. The figures are listed below.

FIG. 1 is a perspective view of a RF filter according to one embodiment;

FIG. 2 illustrates an electromagnetic wave radiated by one single ring of wire in one direction in a plane and an electromagnetic wave reflected by various other rings of the wire;

FIG. 3 illustrates an electromagnetic wave radiated outwards by one single ring of the wire and an electromagnetic wave reflected by an adjacent ring of the wire in a plane taken by line III-III of FIG. 2;

FIG. 4 is a plan view of a RF filter according to a second embodiment;

FIG. 5 illustrates a motor having a RF filter according to one embodiment;

FIG. 6 is a perspective view of a RF filter for use in the motor of FIG. 5, according to another embodiment;

FIG. 7 is a perspective view of a RF filter for use in the motor of FIG. 5, according to another embodiment;

FIG. 8 is a perspective view of a RF filter for use in the motor of FIG. 5 according to another embodiment;

FIG. 9 is a perspective view of a RF filter according to another embodiment;

FIG. 10 is a plan view of a RF filter according to another embodiment;

FIG. 11 is a perspective view of a RF filter according to another embodiment;

FIG. 12 is a plan view of a RF filter according to a further embodiment; and

FIG. 13 is a rear view of the RF filter of FIG. 12.

### DETAILED DESCRIPTION OF THE PREFERRED EMBODIMENTS

FIG. 1 is a perspective view of a RF filter 10 according to one embodiment of the present invention. The RF filter 10 includes a conductive wire 12 wrapped with an outer insulating material. The conductive wire 12 is coiled on a hypothetical cylindrical surface along a helical direction to form a hollow cylindrical coil. Opposite terminals of the conductive wire 12 at opposite axial ends of the cylindrical coil form an input end and an output end of the RF filter 10.

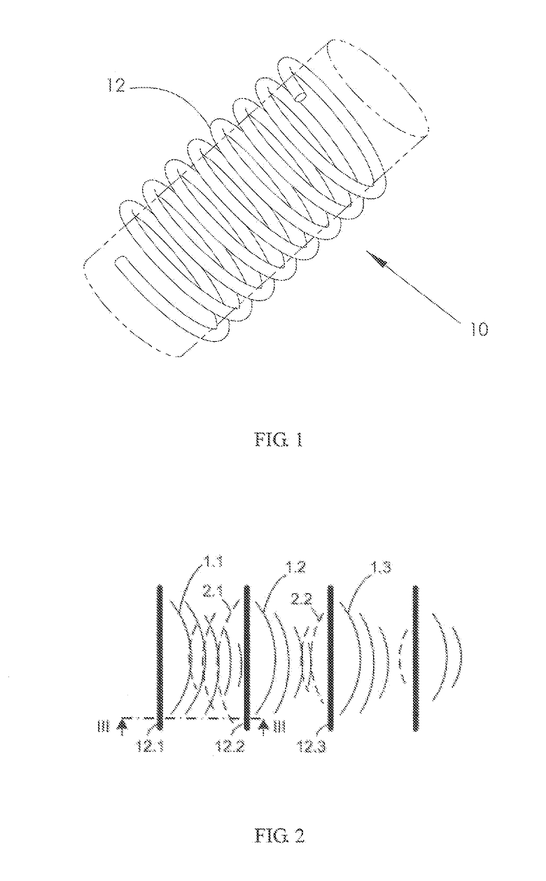

The principle of how the RF filter 10 reduces electromagnetic radiation is described with reference to FIG. 2. FIG. 2 illustrates the reflection of electromagnetic radiation radiated by one single ring of wire along one direction in a plane by various other rings of the wire. After a signal flows into the RF filter 10, a ring 12.1 of the wire radiates outwardly an electromagnetic wave 1.1. When encountering a ring 12.2 of the wire, the electromagnetic wave 1.1 is reflected by the ring 12.2 to form a reflected electromagnetic wave 2.1 which interferes with and hence attenuates the electromagnetic wave 1.1. As a result, the electromagnetic wave 1.1 is attenuated through the ring 12.2 to an electromagnetic wave 1.2 with reduced intensity. Similarly, a ring 12.3 reflects the electromagnetic wave 1.2 to form a reflected electromagnetic wave 2.2 which attenuates the electromagnetic wave 1.2 to form an electromagnetic wave 1.3 with further reduced intensity. If there are further rings of the wire, the intensity of the electromagnetic wave will be further gradually reduced in the similar manner, further detail of which is not described herein.

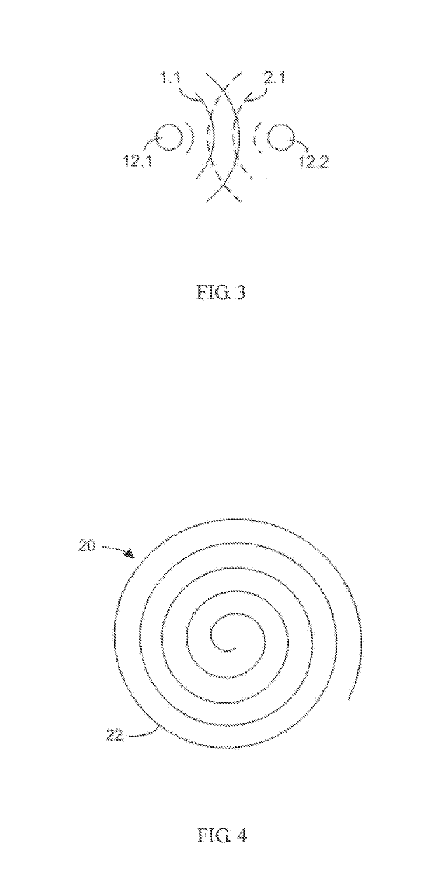

The electromagnetic wave radiated from the wire is transmitted not only in the plane shown in FIG. 2 but in a three-dimensional space centered at the conductive wire, as shown in FIG. 3. The electromagnetic wave 1.1 radiated from the ring 12.1 is transmitted in a three-dimensional space and is partly reflected by the ring 12.2. The reflected electromagnetic wave 2.1 is also transmitted in a three-dimensional space. In the three-dimensional space, the reflected electromagnetic wave 2.1 likewise attenuates the electromagnetic wave 1.1.

As can be seen, except that the electromagnetic waves radiated axially and outwardly from the rings of the wire at the opposite axial ends of the RF filter of FIG. 1 are not reflected by other rings of the wire, the electromagnetic waves radiated from other parts of the rings of the wire at the opposite axial ends and other rings of the wire of the RF filter 10 are more or less attenuated by the electromagnetic waves reflected from the wire. Therefore, the intensity of the electromagnetic waves radiated from the entire coil is greatly reduced. That is, the electromagnetic radiation signal is reduced.

FIG. 4 is a plan view of a RF filter 20 according to a second embodiment. The RF filter 2 includes a conductive wire 22 wrapped with an outer insulating material. The conductive wire 22 is coiled in a plane in a spiral direction to form a coil. Opposite terminals of the conductive wire 12 at inner and outer radial sides of the coil form an input end and an outer end of the RF filter 10. Similar to the above embodiment, except that the electromagnetic wave radiated radially outwardly from an outmost ring of the coil of the RF filter 20 of FIG. 4 is not reflected by other rings of the coil, the electromagnetic waves radiated from other parts of the outmost ring of the coil and other rings of the coil of the RF filter 20 are more or less attenuated by the electromagnetic waves reflected from the wire. Therefore, the intensity of the electromagnetic waves radiated outwardly from the entire coil is greatly reduced. That is, the electromagnetic radiation signal is reduced.

As can be seen from the above description, in the first embodiment, the electromagnetic waves radiated from the axially outer sides of the rings of the coil at the axial ends of RF filter 10 are not reflected by other rings of the wire. Therefore, the RF filter 10 generates a greater electromagnetic radiation at the axial ends in the axial direction than at other parts. In the second embodiment, the electromagnetic wave radiated from the radially outer side of the outmost ring of the coil of RF filter 20 is not reflected by other rings of the wire. Therefore, the RF filter 20 generates a greater electromagnetic radiation at the radially outer side in the radial direction than at other parts. In practice, the RF filters 10 and 20 can be chosen depending upon actual requirements.

FIG. 5 illustrates a motor 30 having a RF filter which is connected with a power supply according to one embodiment. The motor 30 includes a stator and a rotor. The stator includes stator magnetic poles 32, brushes 34, 34′, RF filters 36, 36′, and motor terminals 33, 33′ for connecting with positive and negative power terminals. The stator magnetic poles 32 may be permanent magnetic poles or magnetic poles formed by electromagnetic coils. The brushes 34, 34′ are connected to the motor terminals through the RF filters 36, 36′, respectively. The rotor includes a commutator 38 and rotor magnetic poles. The rotor magnetic poles are formed by coils wound around a rotor core. The motor 30 may have a configuration known in the art which is not described herein in further detail. Two brushes are illustrated in FIG. 5. It should be understood, however, that when the motor has more than two brushes, the number of the RF filters may increase accordingly or a single RF filter may be connected with multiple brushes with the same polarity.

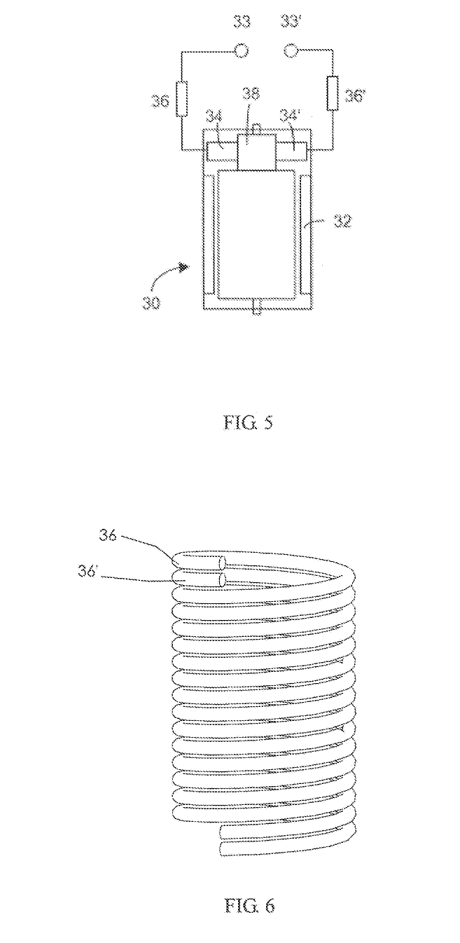

In the case of two RF filters 36, 36′, each RF filter 36, 36′ may be similar to the RF filter of FIG. 1 (RF filter 10 in FIG. 1) that are separately disposed. Opposite terminals of each RF filter are connected to a corresponding motor terminals (positive and negative power terminals) and a corresponding brush. In another embodiment, for example, as shown in FIG. 6, the two RF filters 36, 36′ extend in parallel on the same hypothetical cylindrical surface (illustrated in broken lines in FIG. 1) in the same helical direction. As such, the RF filters occupy a reduced space.

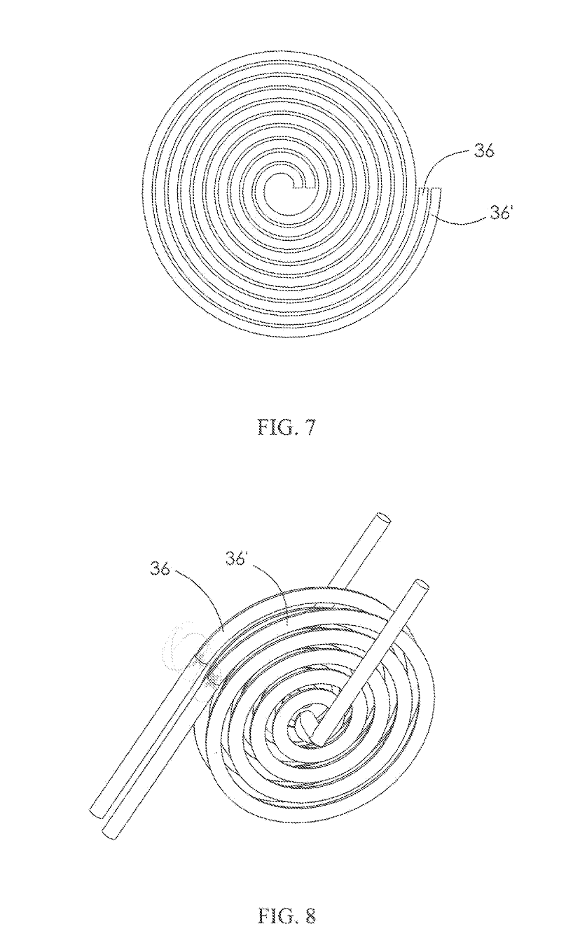

Alternatively, the two RF filters 36, 36′ may be similar to the RF filter of FIG. 4 (RF filter 20) that are separately disposed in another manner, for example, mounted in parallel to a circuit board, with opposite terminals connected to corresponding motor terminals and corresponding brushes. In another embodiment, as shown in FIG. 7, the two RF filters 36, 36′ extend in parallel in the same plane. This can increase the efficiency of winding the wire of the filter. In still another embodiment, as shown in FIG. 8, the two RF filters 36, 36′ are symmetrically disposed in two parallel planes, which facilitate attenuation of the electromagnetic waves of the RF filters that are radiated to each other, thereby achieving a better result of reducing the electromagnetic radiation signal.

In the motor employing the RF filters as described above, the RF filters occupy a portion of the space between the brushes and power terminals. Therefore, the conventionally used straight conductive wires or conductive strips are greatly reduced in length or even completely replaced with the RF filters. As such, the electromagnetic radiation radiated from the entire motor is reduced.

A motor winding may produce electromagnetic waves when the direction of the electrical current in the winding is alternated with high frequency. Therefore, besides use in the brush motor as described above, the above RF filters may be equally used in brushless motors. The brushes of the brush motor and inductors and capacitors that are possibly connected between the motor or power terminals and brushes, or a circuit for converting the power in the brushless motor may be collectively termed as an internal circuit. As such, the RF filters are connected between the power terminals and the internal circuit. In addition, the number of RF filters connected between one brush and one power terminal is not intended to be limited to one. In another embodiment, multiple RF filters connected in series, for example, by a straight conductive wire, can be connected between one brush and one power terminal.

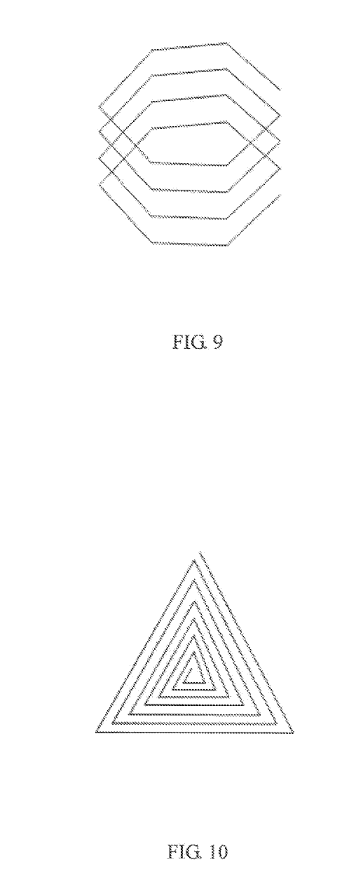

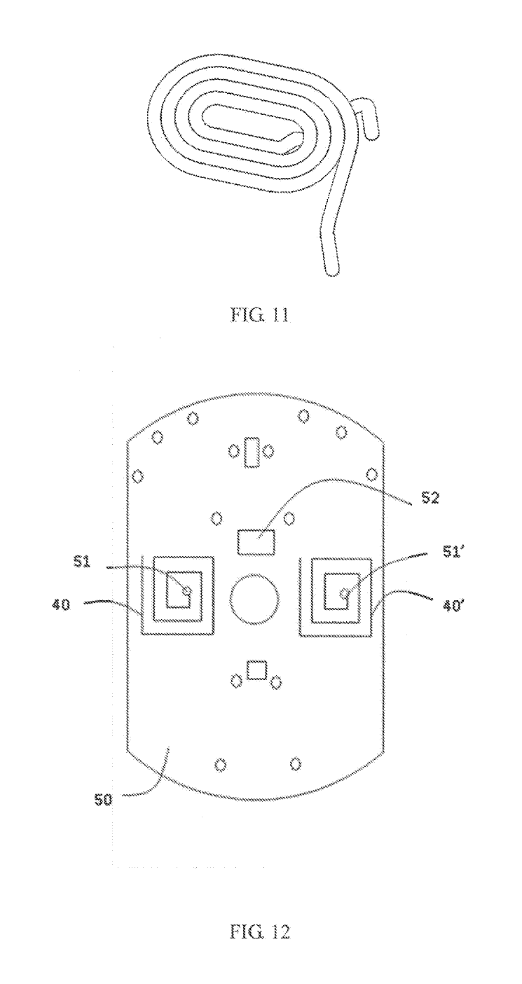

In the above embodiments, the RF filters are formed by curved wires in standard helical or spiral shape. However, the wires of the RF filters may be in modified helical or spiral shapes in alternative embodiments. For example, each ring of the helical-shaped wire has a polygon shape in the embodiment shown in FIG. 9, each ring of the spiral-shaped wire has a triangle shape in the embodiment shown in FIG. 10, and each ring of the spiral-shaped wire has an oval shape in the embodiment shown in FIG. 11, all of which can achieve substantially the same results. Therefore, it is not intended to limit the helical or spiral shaped wire mentioned in the present invention to the curved shape, and the helical or spiral shape with oval rings, triangle rings, square rings or polygonal rings therefore belongs to the helical or spiral shape mentioned in this disclosure. In other words, the helical shape mentioned in this disclosure is not intended to be limited to the standard helical shape. Rather, any shape that extends outwardly along a particular path in a generally helical direction in a ring-by-ring manner should be considered as the helical shape of the present invention. The particular path may be in a shape similar to triangle, square, polygon, oval or the like.

In the various embodiments above, the RF filters are formed by the wires wrapped with insulating material. This type of wires can be easily manufactured, has a low cost and is readily commercially available. The function of the insulating material is to avoid a short-circuit between adjacent rings of the wire. It should be understood that the RF filter is not limited to be made from the conductive wire with insulating material. In another embodiment, the RF filter may also be made from a conductive wire without the insulating material. In that case, the rings of the wire are spaced apart such that a short-circuit there between is avoided, for example, as in FIG. 1. Alternatively, if the adjacent rings of the wire are to contact with each other, an insulating sheet or film is disposed at only the contact area of the adjacent rings to avoid a short-circuit there between.

In the various embodiments above, the RF filters are separate components. As shown in FIG. 12, in an alternative embodiment, instead of the separate components, the RF filters 40, 40′ are directly printed on the circuit board 50. That is, the conductive wires forming the RF filters 40, 40′ are conductors printed on the printed circuit board 50. The RF filters 40, 40′ are electrically connected with the respective terminal of the motor. The RF filters 40, 40′ are printed on the circuit board, which facilitates manufacture of the motor, reduces the number of components of the motor and saves the space around the printed circuit board 50.

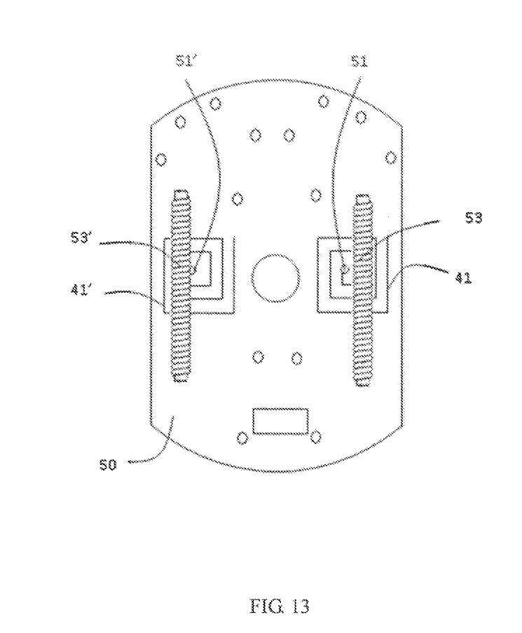

In addition, referring to FIG. 13, when there is a need for RF filters with higher performance, i.e. RF filters having greater length or having a greater number of turns of conductive wire, but a first surface of the circuit board 50 has not enough area for enlarging the RF filters, it is only needed to print additional RF filters 41, 41′ on a second surface of the circuit board 50 and connect the RF filters 41, 41′ in series to the RF filters 40, 40′ on the first surface through connection holes in the circuit board known as vias 51, 51′, respectively, such that the two RF filters 40 and 40′ form an integrated RF filter and the two RF filters 41 and 41′ form an integrated RF filter. This manner of upgrading is easier and more flexible. Preferably, the circuit board 50 further includes other electrical components 52, 53, 53′, wherein the electrical components 53, 53′ are inductors. As shown in FIG. 13, the inductors 53, 53′ are disposed over the RF filters 41, 41′. The RF filters 41, 41′ are printed on the circuit board 50 and, therefore, do not affect the disposing of the inductors 53, 53′. As such, the printed RF filters allow more electrical components to be disposed on a circuit board having a specific size.

In the description and claims of the present application, each of the verbs “comprise”, “include”, “contain” and “have”, and variations thereof, are used in an inclusive sense, to specify the presence of the stated item or feature but do not preclude the presence of additional items or features.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

The embodiments described above are provided by way of example only, and various other modifications will be apparent to persons skilled in the field without departing from the scope of the invention as defined by the appended claims.

1. A RF filter comprising a conductive wire, the conductive wire coiled on a hypothetical cylindrical surface in a helical manner to form a hollow cylindrical coil, opposite terminals of the conductive wire at opposite axial ends of the cylindrical coil forming an input end and an output end of the RF filter.

2. The RF filter of claim 1, wherein the conductive wire is wrapped with an outer insulating material.

3. A RF filter comprising a conductive wire, the conductive wire coiled in a plane in a spiral manner to form a coil, opposite terminals of the conductive wire at inner and outer radial ends of the coil forming an input end and an output end of the RF filter.

4. The RF filter of claim 3, wherein the conductive wire is wrapped with an outer insulating material.

5. A motor comprising:
motor terminals for connecting with an external power supply;
an internal circuit electrically connected to the motor terminals; and
a RF filter connecting the internal circuit to one of the motor terminals,
wherein the RF filter comprises a conductive wire formed in a coil having first and second terminals, the first terminal being connected to one of the motor terminals and the second terminal being connected to the internal circuit, the coil being wound in a manner to attenuate electromagnetic radiation from the motor.

6. The motor of claim 5, wherein the conductive wire is coiled on a hypothetical cylindrical surface in a helical manner to form a hollow cylindrical coil.

7. The motor of claim 6, wherein the motor comprises two such RF filters, with the first terminal of each coil being connected to a respective one of the motor terminals.

8. The motor of claim 7, wherein the conductive wires of the two RF filters extend in parallel on the same hypothetical cylindrical surface in the same helical direction, and at least one of the conductive wires is wrapped with an outer insulating material.

9. The motor of claim 5, wherein the RF filter comprises a conductive wire coiled in a plane in a spiral manner to form the coil.

10. The motor of claim 9, wherein the motor comprises two such RF filters, with the first terminal of each coil being connected to a respective one of the motor terminals.

11. The motor of claim 10, wherein the conductive wires of the two RF filters are coiled together in a single plane.

12. The motor of claim 10, wherein the motor comprises two such RF filters, and the coils of the two RF filters are symmetrically disposed in two parallel planes.

13. The motor of claim 10, wherein the motor comprises two such RF filters, and the conductive wires are conductive traces formed on a circuit board.

14. The motor of claim 13, wherein the motor further comprises a circuit board, each RF filter is printed on the circuit board and is electrically connected to the internal circuit through a printed circuit on the circuit board.

15. The motor of claim 10, wherein the motor further comprises a circuit board with a printed circuit, the RF filter is printed on the circuit board and is electrically connected with the connecting terminals and internal circuit through the printed circuit on the circuit board.

16. The motor of claim 15, wherein the circuit board includes a first surface and a second surface, the RF filter includes a first RF filter portion printed on the first surface and a second RF filter portion printed on the second surface, the first RF filter portion and the second RF filter portion are aligned with each other and are connected in series through a hole in the circuit board.

17. The motor of claim 11, wherein the conductive wire of at least one of the RF filters has an insulating cover.

18. The motor of claim 5, wherein rings of the coil are in the shape of one of a circle, an oval, a triangle, a square, and a polygon.

19. The motor of claim 5, wherein the conductive wire extends in a plane to expand outwardly in a continuous ring-by-ring manner.
